(19) United States
(12) Patent Application Publication
(10) Pub. No.: US 2025/0185311 A1
(43) Pub. Date: Jun. 5, 2025

(54) SUBSTRATE NOISE ISOLATION STRUCTURES FOR ELECTRONIC DEVICES

(71) Applicant: XILINX, INC., San Jose, CA (US)

(72) Inventors: Jing JING, San Jose, CA (US); Jane Wang SOWARDS, Fremont, CA (US); Shuxian WU, San Jose, CA (US)

(21) Appl. No.: 18/526,364

(22) Filed: Dec. 1, 2023

(51) Int. Cl. H01L 29/06; H01L 21/761; H01L 21/768; H01L 23/48; H01L 23/522; H01L 25/065

(52) U.S. Cl. CPC H10D 62/102; H01L 21/761; H01L 21/76898; H01L 23/481; H01L 23/5226; H01L 25/0657

(57) ABSTRACT

Techniques for substrate noise isolation structures for electronic devices are provided. The disclosed techniques greatly reduce substrate noise induced by circuits in integrated circuits (ICs) that include Fin Field Effect Transistors (FinFETs). In an example, an electronic device is provided that includes a first circuit and a second circuit formed on a substrate, a first guard structure formed in the substrate, and a plurality of vias formed through the substrate. The first guard structure formed in the substrate is disposed between the first circuit and the second circuit. The plurality of vias formed through the substrate contact the first guard structure.

### TECHNICAL FIELD

Examples of the present disclosure generally relate to electronic circuits and, in particular, to substrate noise isolation structures for electronic devices.

### BACKGROUND

Silicon integrated circuits (ICs) suffer from substrate coupling because the substrates are not good insulators. Coupling electric signals between circuits through the semiconductor substrate can cause noise interference and affect the normal function of the circuits. Thus, reducing unwanted substrate noise is important to ensure the normal function and performance of ICs with silicon substrates in both bulk and Fin Field Effect Transistor (FinFET) technologies.

Various techniques have been employed in ICs to reduce substrate coupling. One technique is to add high-resistance paths in the substrate. Another technique is to add guard rings around sensitive circuits. For bulk complementary metal oxide semiconductor (CMOS) technologies, the guard rings are continuous, which forms good isolation between circuits. For FinFET technologies, however, the guard rings are no longer continuous in the vertical direction and the oxide definition (OD) width is limited by the maximum Fin numbers in each FinFET technology. In this case, substrate noise can leak through the gaps in the guard rings and cause unwanted noise and interference. The inventors have found the substrate noise to be 30 dB higher in cases of a discontinuous guard ring. As technology advances, the substrate coupling becomes more severe, since the distance between circuits becomes smaller.

### SUMMARY

Techniques for substrate noise isolation structures for electronic devices are provided. The disclosed techniques greatly reduce substrate noise induced by circuits in integrated circuits (ICs) that include Fin Field Effect Transistors (FinFETs). In an example, an electronic device is provided that includes a first circuit and a second circuit formed on a substrate, a first guard structure formed in the substrate, and a plurality of vias formed through the substrate. The first guard structure formed in the substrate is disposed between the first circuit and the second circuit. The plurality of vias formed through the substrate are disposed between the first guard structure and the first guard structure.

The plurality of vias are disposed between the first circuit and the second circuit. The plurality of vias may also be in a plurality of columns.

The plurality of vias may be formed in an un-doped region of the substrate. The un-doped region may be adjacent an N+ doped region.

The plurality of vias can be disposed on one, two, three or four sides of the second circuit. The plurality of vias may circumscribe the first guard structure. The plurality of vias may be circumscribed by a second guard structure that also circumscribes the first guard structure.

In some examples, an electronic device is provided that includes a first IC die stacked on a second IC die. The first IC die and the second IC both include separate noise isolation structures. The first IC die includes a first circuit and a second circuit formed on a substrate, a first guard structure formed in the substrate, and a plurality of vias formed through the substrate. The first guard structure formed in the substrate is disposed between the first circuit and the second circuit. The plurality of vias are formed through the substrate adjacent the first guard structure. The first guard structure and plurality of vias form a noise isolation structure of the first IC die. The first IC die also includes a via stack formed through FEOL and BEOL regions of the first IC die. The via stack is electrically connected to the plurality of vias. The via stack is electrically connected to a noise isolation structure of the second IC die.

In another example, an electronic device is provided that includes a first substrate having a front end of the line (FEOL) region and a back end of the line (BEOL) region formed thereon. The FEOL region contains a least a portion of a first circuit and a second circuit. The FEOL region and the BEOL region comprises at least a portion of a first integrated circuit (IC) die. A first guard structure is formed in the first substrate and is disposed between the first circuit and the second circuit. The first guard structure includes a first group of discontinuous pairs of N+ and P+ wells disposed along a first column. A plurality of vias formed through the first substrate adjacent the first guard structure. The plurality of vias are disposed between the first circuit and the second circuit. A via stack are formed through the FEOL and BEOL regions. The via stack is electrically connected to one of the plurality of vias formed through the first substrate.

In yet another example, a method of manufacturing an electronic device is provided. The method includes forming a first circuit and a second circuit on a substrate. The method further includes forming a first guard structure in the substrate between the first circuit and the second circuit, where the first guard structure including first discontinuous pairs of N+ and P+ diffusions arranged in a column. The method additionally includes connecting a plurality of vias formed through the substrate to the first guard structure.

In still another example, a method of manufacturing an electronic device is provided that includes forming a first circuit and a second circuit on a substrate; forming a first guard structure in the substrate between the first circuit and the second circuit, the first guard structure including first discontinuous pairs of N+ and P+ diffusions arranged along an axis; forming a second guard structure in the substrate between the first circuit and the second circuit, the first guard structure including second discontinuous pairs of N+ and P+ diffusions arranged along the axis, the first discontinuous pairs staggered relative to the second discontinuous pairs; and forming a plurality of vias through the substrate between the first guard structure and the second guard structure, the plurality of vias formed between the first circuit and the second circuit.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a plan view of an electronic device according to an example.

FIGS. 2A-B are plan views depicting a diffusion region of a guard structure according to examples.

FIG. 2C is a partial sectional view of the IC die illustrating a diffusion region of a guard structure disposed adjacent a portion of a via guard structure according to an example.

FIG. 3A is a plan view depicting a substrate noise isolation structure according to an example.

FIG. 3B is a plan view depicting a substrate noise isolation structure according to another example.

FIG. 3C is a plan view depicting a substrate noise isolation structure according to another example.

FIG. 4 is a sectional view of the IC die of FIG. 1 illustrating a substrate noise isolation structure having guard structures separated by a via guard structure according to an example.

FIG. 5 is a sectional view of another electronic device having stacked IC dies, each IC die having a via guard structure connected via a via stack according to an example.

FIG. 6 is a plan view of an electronic device having a substrate noise isolation structure that includes via guard structure disposed between a noise source circuit and a noise receiver circuit according to another example.

FIG. 7 is a plan view of another electronic device having a substrate noise isolation structure that includes via guard structure disposed on three sides of a noise receiver circuit according to another example.

FIG. 8 is a plan view of another electronic device having a substrate noise isolation structure that includes via guard structure disposed on all sides of a noise receiver circuit according to another example.

FIG. 9 is a flow diagram depicting a method of manufacturing an electronic device according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the claimed invention or as a limitation on the scope of the claimed invention. In addition, an illustrated example need not have all the aspects or advantages shown. An aspect or an advantage described in conjunction with a particular example is not necessarily limited to that example and can be practiced in any other examples even if not so illustrated or if not so explicitly described.

Substrate noise isolation structures for integrated circuit dies, chip packages and electronic devices are provided. The disclosed noise isolation structures greatly reduce substrate noise induced by circuits in integrated circuits (ICs) that include Fin Field Effect Transistors (FinFETs) or other type of transistor. In an example, multiple oxide definition (OD) guard rings of N+/P+ types with a shifted pattern are used to implement a substrate noise isolation scheme that leverages grounded through silicon vias (TSV) as part of an isolation structure that is particularly effective in preventing noise transmission in integrated circuit die having thinned substrates. The isolation scheme can be placed between circuit blocks as a wall, or can surround circuit blocks, to suppress substrate noise coupling.

In one example, the noise isolation scheme incorporates two mechanisms: N+/P+ guard ring pairs and grounded TSVs. The grounded TSVs are connected to a ground plane or a dedicated grounding structure, such as a P+ guard ring, providing a low-impedance path for substrate noise currents. The grounded TSV connection ensures that the noise currents flow away from the sensitive circuitry, preventing noise from coupling into the functional circuits of the IC die.

The guard ring may include a shifted pattern using discrete diffusion N+/P+ pairs in FinFET processes to enhance the efficiency of noise isolation. The use of N+/P+ guard ring pairs and grounded TSVs in combination in a noise isolation effectively suppresses substrate noise and strengthens the isolation performance in 3D technology with thinned down silicon substrates. By reducing substrate noise, the risk of performance degradation, timing errors, and functional failures due to noise-induced glitches or disturbances is effectively reduced, thus improving the overall reliability and lifespan of the electronic devices incorporating this novel noise isolation structure.

Advantageously, by effectively reducing substrate noise in thinned-down substrates, the noise isolation structure enables the successful integration of noise sensitive analog circuits in a 3D stacked devices. Fabrication of the noise isolation structure is compatible with existing fabrication processes used in CMOS and 3D stacking technologies, beneficially allowing improved device performance and cost-effective production. The noise isolation structure provides isolation efficiency comparable to that of conventional isolation substrates used in thick silicon substrates. Additionally, the novel noise isolation structure can be readily used in stacked device integration, and can be seamlessly integrated with the existing process. Accordingly, these advantages make the novel noise isolation structure an attractive solution for improving the performance of 3D stacked product with thinned-down substrates. These and further aspects are described below with respect to the drawings.

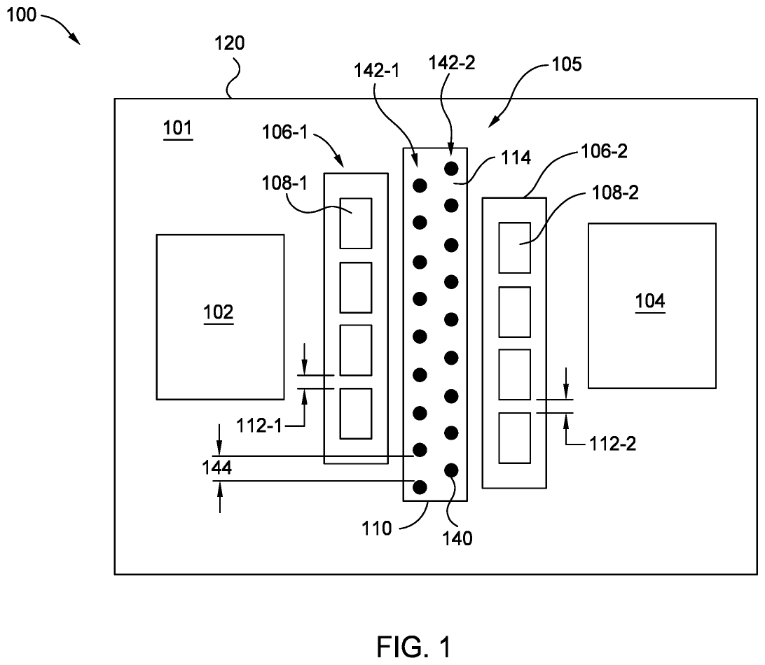

FIG. 1 is a plan view of an electronic device 100 according to an example. In the example depicted in FIG. 1, the electronic device 100 is in the form of at least one integrated circuit (IC) die 120. However, the electronic device 100 may also be a stack of IC dies 120, a chip package having one or more IC dies 120, or other type of electronic device that includes at least one IC die 120.

The IC die 120 includes a semiconductor substrate 101 (e.g., silicon), a noise source circuit 102, a noise receiver circuit 104, and a substrate noise isolation structure 105. The noise source circuit 102 and the noise receiver circuit 104 are separated by the substrate noise isolation structure 105. The noise source circuit 102 and the noise receiver circuit 104 each include a plurality of transistors. In an example, at least one of the noise source circuit 102 and the noise receiver circuit 104 includes FinFETs. The metal layers that interconnect the transistors to form the circuits 102, 104 are omitted from FIG. 1 for clarity.

Exemplary noise source circuits 102 may include power electronics, among others. Noise source circuits 102 that include power electronic systems, such as converters and inverters, often operate at high currents and switching frequencies. Substrate noise generated by power electronic components in the noise source circuit 102 can negatively impact the performance of the IC die 102, leading to issues such as electromagnetic interference (EMI) and reliability concerns in the adjacent noise receiver circuit 104. The substrate noise isolation structure 105 beneficially reduces the impact to the sensitive circuitry of the noise receiver circuit 104 from operation of the noise source circuit 102, thus, reducing the risk of EMI, improving reliability, and ensuring proper operation of power electronic systems.

Examples of noise receiver circuit 104 include RF and wireless system circuitry, among other. Noise receiver circuits 104 that include RF and wireless system circuitry, such as transceivers and amplifiers, can have degraded the signal integrity due to substrate noise, which can impact the overall IC die performance. The substrate noise isolation structure 105 beneficially reduces the propagation of substrate noise within the IC die 120, leading to improved signal quality, reduced interference, and enhanced performance of the noise receiver circuit 104.

Other examples of noise receiver circuit 104 include optoelectronic circuitry. Noise receiver circuits 104 that include optoelectronic circuitry, such as photodetectors and optical transceivers, can be affected by substrate noise. The substrate noise isolation structure 105 significantly reduces noise coupling and maintaining the signal integrity of optoelectronic components.

As discussed above, the substrate noise isolation structure 105 is disposed between the noise source circuit 102 and the noise receiver circuit 104. In the present example, the substrate noise isolation structure 105 forms a wall between the circuits 102, 104. In other examples (described below), the substrate noise isolation structure 105 can be implemented as one or more rings surrounding one of the circuits 102, 104. The substrate noise isolation structure 105 is configured to reduce substrate coupling between the circuits 102, 104. For example, as shown in FIG. 1, the noise source circuit 102 is a source of substrate noise on the electronic device 100, and the noise receiver circuit 104 is sensitive to substrate noise on the electronic device 100. The substrate noise isolation structure 105 reduces substrate noise at the noise receiver circuit 104 that is generated by the noise source circuit 102.

Although in the example depicted in FIG. 1 the substrate noise isolation structure 105 is shown surrounding the noise receiver circuit 104, the substrate noise isolation structure 105 may alternatively surround the noise source circuit 102. Optionally, both the noise source circuit 102 and the noise receiver circuit 104 may be separated by separate the substrate noise isolation structures 105. Thus, in the examples described herein with reference to any of the Figures, the location of the noise source circuit 102 and the noise receiver circuit 104 may be reversed.

The substrate noise isolation structure 105 includes a plurality of guard structures 106 and a via guard structure 110. In one example, guard structures 106-1, 106-2 and the via guard structure 110 are formed in the semiconductor substrate 101. The via guard structure 110 may be disposed to either side of the guard structures 106-1, 106-2, and in the example depicted in FIG. 1, the via guard structure 110 is disposed between the guard structures 106-1, 106-2.

Each of the guard structures 106 comprises a column of discrete diffusion regions extending along a Y-axis of an X-Y plane of the semiconductor substrate 101. As shown, the diffusion regions of the guard structures 106 are discontinuous along the Y-axis. For example, for FinFET technologies, the oxide definition (OD) width is limited by the maximum Fin numbers in each FinFET technology. Thus, it is not possible to form continuous diffusion regions along the axis of the OD width (e.g., the Y-axis).

As shown in FIG. 1, the guard structure 106-1 includes diffusion regions 108-1 separated by gaps 112-1. The guard structure 106-2 includes diffusion regions 108-2 separated by gaps 112-2. The guard structures 106-1 and 106-2 are parallel to each other along the Y-axis and are staggered with respect to each other. That is, the gaps 112-1 are not aligned with the gaps 112-2. Stated differently, the diffusion regions 108-2 of the guard structure 106-2 block the gaps 112-1 between the diffusion regions 108-1 of the guard structure 106-1 along the X-axis. Thus, there is no path parallel to the X-axis through the substrate noise isolation structure 105 between the circuits 102, 104. In this manner, the staggered guard structures reduce substrate coupling between the circuits 102, 104. While two staggered guard structures 106-1 and 106-2 are shown, a plurality of guard structures 106 can be formed in the semiconductor substrate 101 between the circuits 102, 104 and staggered with respect to each other.

The via guard structure 110 is formed in the substrate 101 and is connected to ground. The via guard structure 110 generally includes a plurality of vias 140. In one example, the plurality of vias 140 are coupled to ground. The plurality of vias 140 may be formed in an un-doped region 114 of the substrate 101. The un-doped region 114 of the substrate 101 is distinctly separate from the doped regions of the guard rings 106. The un-doped region 114 may be adjacent an N+ doped or P+ doped region. In the example depicted in FIG. 1, the un-doped region 114 is adjacent an N+ region.

The plurality of vias 140 may be arranged in a single column 142, or be arranged in multiple columns 142, such as the columns 142-1 and 142-2 shown in FIG. 1. Alternatively, the plurality of vias 140 may have other arrangements. The columns 142-1, 142-2 are oriented in the same direction as the guard structures 106-1 and 106-2, which in one example is parallel to the Y-axis. The vias 140 within one column 142-1 have a spacing 144. The spacing 144 of one column 142-1 may be the same or different than the spacing 144 in another column 142-2. In one example, the vias 140 of one column 142-1 is staggered relative the vias 140 of another column 142-2, such that a via 140 of the column 142-1 is aligned with the gap created by the spacing 144 of two vias 140 of column 142-2.

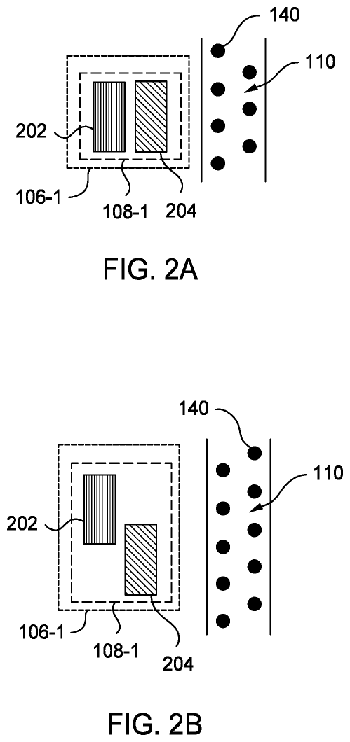

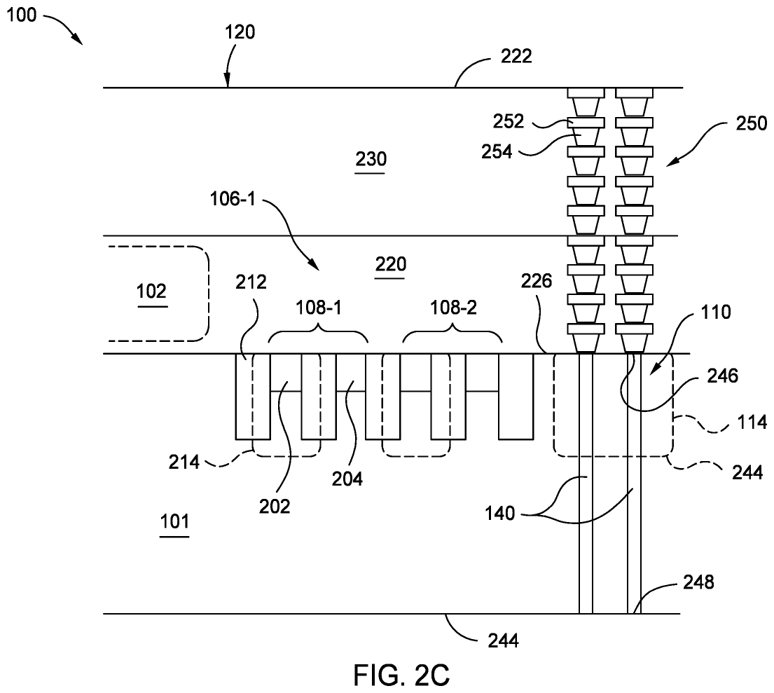

FIG. 2A is a plan view depicting a diffusion region 108-1 of the guard structure 106-1 disposed adjacent a portion of the via guard structure 110 according to an example. Any diffusion region 108 of the guard structures 106 is configured similar to that shown in FIG. 2A. As shown in FIG. 2A, the diffusion region 108-1 includes an N+ diffusion 202 and a P+ diffusion 204. The N+ diffusion 202 and the P+ diffusion 204 are referred to as an N+/P+ pair of diffusion regions. The N+ diffusion 202 comprises a heavily doped region of the semiconductor substrate 101 that has a larger electron concentration than hole concentration and an donor impurity concentration N that satisfies the inequality Na³>>1, where a is the Bohr radius of the impurity state. The P+ diffusion 204 comprises a heavily doped region of the semiconductor substrate 101 that has a larger hole concentration than electron concentration and a donor impurity concentration N that satisfies the inequality Na³>>1. By including both N+ and P+ diffusions, the guard structures 106 reduce both electron and hole coupling between the circuits 102, 104.

FIG. 2B is a plan view depicting a diffusion region 108-1 of the guard structure 106-1 disposed adjacent a portion of the via guard structure 110 according to another example. Any diffusion region 108 of the guard structures 106 is configured similar to that shown in FIG. 2B. As shown in FIG. 2B, the N+ diffusion 202 and the P+ diffusion 204 are staggered with respect to one another, rather than being substantially aligned as shown in FIG. 2A. Thus, the P+ diffusion regions can block the gaps between the N+ diffusion regions or vice versa.

FIG. 2C is a partial sectional view of the IC die 120 illustrating the diffusion region 108-1 of the guard structure 106-1 disposed adjacent a portion of the via guard structure 110. The IC die 120 generally includes the substrate 101, a front end of the line (FEOL) region 220, and a back end of the line (BEOL) region 230. The FEOL region 220 is formed on a top surface 226 of the substrate 101, and also includes the N+, P+ diffusions 202, 204 disposed below the surface 226. The FEOL region 220 generally includes the functional circuitry that comprises the noise source circuit 102 and the noise receiver circuit 104. The BEOL region 230 is formed on the FEOL region 220 opposite the substrate 101. The BEOL region 230 generally includes interconnect metalization to connecting functional circuitry of within the IC die 120, and connecting functional circuitry of the IC die 120 to other IC dies, interposers, package substrates or other components of a chip package of the electronic device 100. The top of the BEOL region 230 forms a top surface 222 of the IC die 120, while the bottom surface of the substrate 101 forms a bottom surface 224 of the IC die 120.

As shown in FIG. 2C the N+ and P+ diffusion regions 202, 204 are formed in the semiconductor substrate 101. The N+ and P+ diffusion regions 202, 204 of the N+/P+ pair 108-1 are separated by a shallow trench isolation (STI) 212. The diffusion regions of the N+/P+ pair 108-2 are also separated by an STI 212. The N+/P+ pairs 108-1, 108-2 are also separated by an STI 212. In an example, the P+ diffusion regions 204 are formed directly in the semiconductor substrate 101, which can be a p-type silicon substrate. The N+ diffusion regions 202 are formed in n-wells 214, which are formed in the semiconductor substrate 101. In other examples, the semiconductor substrate 101 can be an n-type substrate, the N+ diffusion regions 202 can be formed directly in the substrate, and the P+ diffusion regions 204 can be formed in p-wells.

The via guard structure 110 is shown formed in the un-doped region 114 adjacent the guard structure 106-1. The un-doped region 114 is separate from the diffusion regions 202, 204. The vias 140 of the via guard structure 110 have a top surface 246 and a bottom surface 248. The top surface 246 of the vias 140 are generally coplanar with the top surface 226 of the substrate 101. In the example depicted in FIG. 2C, the bottom surface 248 of the vias 140 are generally coplanar with the bottom surface 224 of the substrate 101/IC die 120. Alternatively, the bottom surface 248 of the vias 140 may be disposed between a bottom 244 of the un-doped region 114 and the bottom surface 224 of IC die 120, be located about the depth as the bottom 244 of the un-doped region 114, are be disposed between the bottom 244 of the un-doped region 114 and the top surface 226 of substrate 101.

The vias 140 of the via guard structure 110 may optionally be electrically connected to one or more via stacks 250 that extends through the FEOL and BEOL regions 220, 230 to the top surface 222 of the IC die 120. The via stack 250 is generally formed from vias 254 and line segments 252 that formed in the metal layers comprising the FEOL and BEOL regions 220, 230. The via stacks 250 provide additional shielding between the noise source and noise receiver circuits 102, 104. The via stacks 250 also facilitate connecting a via guard structure 110 of one IC die 120 with the via guard structure 110 of another IC die 120 when the IC dies 120 are stacked together.

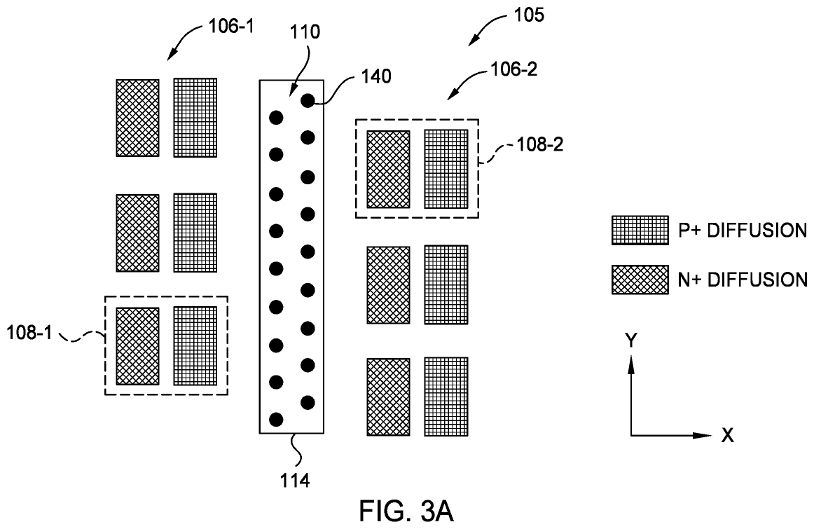

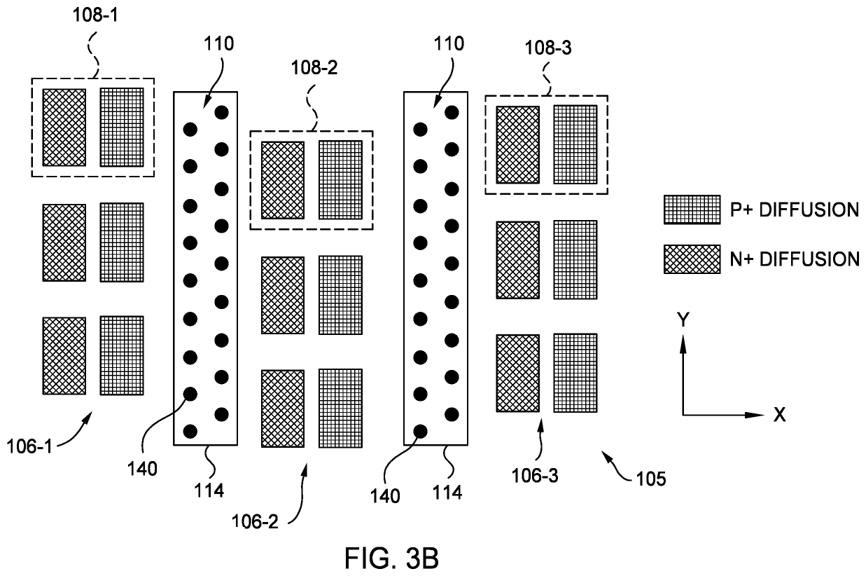

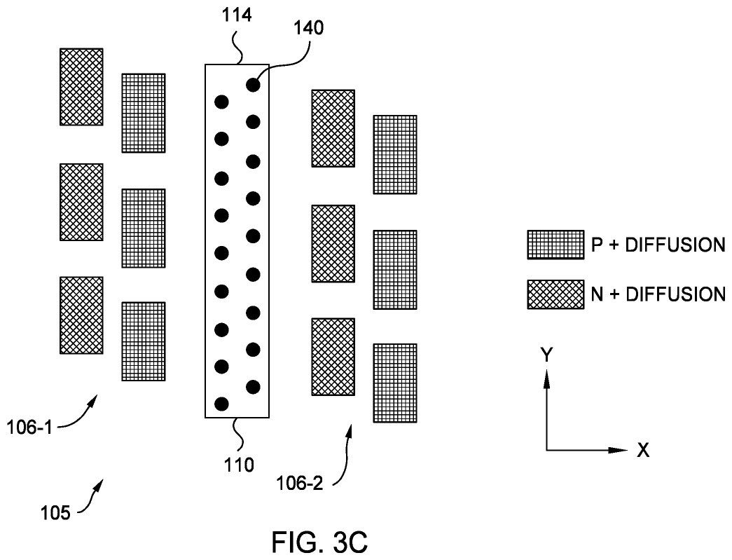

FIG. 3A is a plan view depicting the substrate noise isolation structure 105 according to an example. In the example of FIG. 3A, the substrate noise isolation structure 105 includes two guard structures 106-1 and 106-2 separated by the via guard structure 110. Alternatively, the two guard structures 106-1 and 106-2 of the substrate noise isolation structure 105 may be adjacent each other with the at least one via guard structure 110 disposed adjacent one or both of the guard structures 106-1, 106-2.

Each guard structure 106 comprises discontinuous pairs 108 of N+ and P+ diffusion regions along the Y-axis. The via guard structure 110 and the vias 140 disposed therein are also oriented along the Y-axis. There may be a single column or multiple columns of vias 140.

The N+/P+ pairs 108-1 of the guard structure 106-1 are staggered with respect to the N+/P+ pairs 108-2 of the guard structure 106-2 so that there are no noise paths through the substrate noise isolation structure 105 parallel to the X-axis. That is, the gaps between the N+/P+ pairs 108-1 of the guard structure 106-1 are not aligned with the gaps between the N+/P+ pairs 108-2 of the guard structure 106-2. Furthermore, the incorporation of the grounded via guard structure 110 significantly provides the isolation structure's effectiveness over conventional guard structures only having N+/P+ pairs.

FIG. 3B is a plan view depicting the substrate noise isolation structure 105 according to another example. In the example of FIG. 3B, the substrate noise isolation structure 105 includes three guard structures 106-1, 106-2, and 106-3 separated by via guard structures 110. Alternatively or in addition, the via guard structure 110 may be disposed between the guard structure 106-1 and the noise source circuit 102 and/or may be disposed between the guard structure 106-3 and the noise receiver circuit 104.

Each guard structure 106 comprises discontinuous pairs 108 of N+ and P+ diffusion regions along the Y-axis. The N+/P+ pairs 108-1 of the guard structure 106-1 are staggered with respect to the N+/P+ pairs 108-2 of the guard structure 106-2. Likewise, the N+/P+ pairs 108-2 of the guard structure 106-2 are staggered with respect to the N+/P+ pairs 108-3 of the guard structure 106-3. One skilled in the art will appreciate from FIGS. 3A and 3B that any number of guard structures greater than one can be employed and disposed in a staggered fashion to form the substrate noise isolation structure 105, each substrate noise isolation structure 105 employing at least one via guard structure 110.

FIG. 3C is a plan view depicting the substrate noise isolation structure 105 according to yet another example. In the example of FIG. 3C, the substrate noise isolation structure 105 includes two guard structures 106-1 and 106-2. Alternatively as discussed above, the two guard structures 106-1 and 106-2 of the substrate noise isolation structure 105 may be adjacent each other with the at least one via guard structure 110 disposed adjacent one or both of the guard structures 106-1, 106-2.

Each guard structure 106 comprises pairs of N+ and P+ diffusion regions along the Y-axis. The N+ and P+ diffusion regions are staggered with respect to each other in each guard structure 106. Further, the N+/P+ pairs of the guard structure 106-1 are staggered with respect to the N+/P+ pairs of the guard structure 106-2. Thus, the P+ diffusions in the guard structure 106-2 block the gaps of the P+ diffusions in the guard structure 106-1. The N+ diffusions of the guard structure 106-2 block the gaps of the N+ diffusions of the guard structure 106-1. Within a guard structure 106, the N+ and P+ diffusions are offset from another, rather than aligned with each other as shown in the examples of FIGS. 3A-B. This pattern can be repeated for any number of guard structures 106.

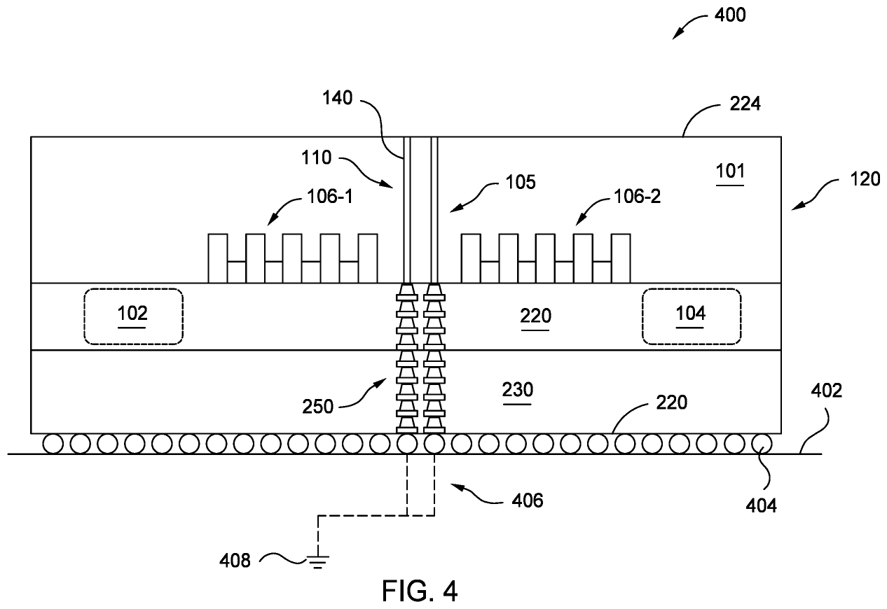

FIG. 4 is a sectional view of the IC die 120 of FIG. 1 illustrating the substrate noise isolation structure 105 having guard structures 106 separated by the via guard structure 110 according to an example. As illustrated in FIG. 4, IC die 120 is mounted to a substrate 402 by interconnects 404, forming an electronic device 400. The substrate 402 may be an interposer, package substrate, printed circuit board, or the like. The interconnects 404 electrically couple the functional and other circuitry of IC die 120 to routing formed in, on and/or through the substrate 402. The interconnects 404 may be hybrid bond, solder bumps, or other suitable IC die-to-substrate connection. In the example depicted in FIG. 4, some of the substrate routing 406 is connected to ground 408. The grounded routing 408 is connected through the interconnects 404 to the via stack 250, and consequently the vias 140.

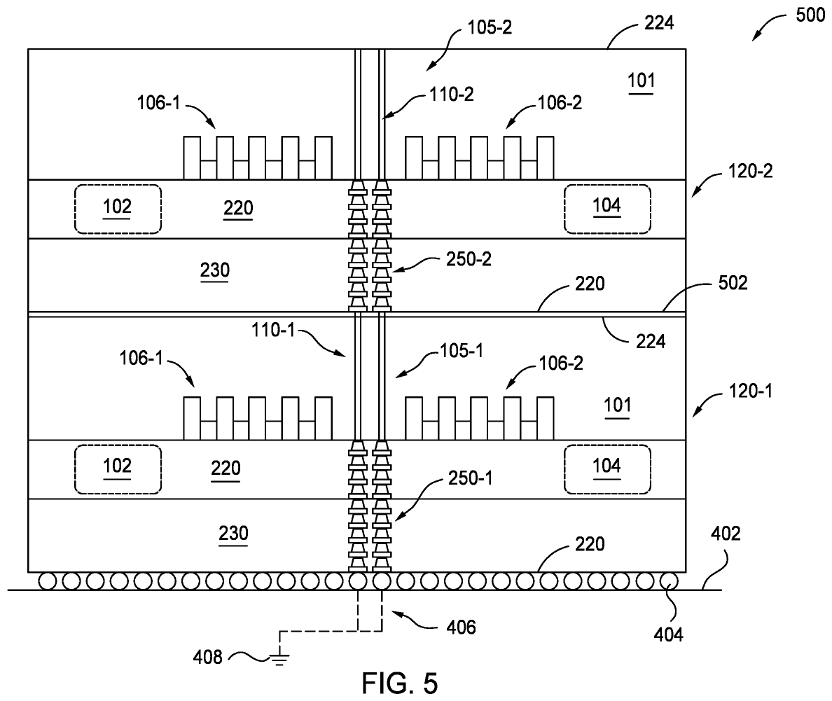

FIG. 5 is a sectional view of another electronic device 500 having stacked IC dies 120-1, 120-2, each IC die 120-1, 120-2 having a via guard structure 110-1, 110-2 connected via a via stack 250-1, 250-2, according to an example. The IC dies 120-1, 120-2 are generally configured as described above with reference to the IC die 120. The first tier IC die 120-1 is mounted to a substrate 404, as described above with reference to FIG. 4. The via stack 250-1 of the first tier IC die 120-1 is coupled to ground 408 through the routing 406 of the substrate 402.

The second tier IC die 120-2 is mounted on and connected to the first tier IC die 120-1 by an interconnect 502. The interconnects 502 may be a hybrid bond, solder bumps, or other suitable IC die-to-IC die connection. In the example depicted in FIG. 5, the interconnects 502 is a hybrid bond that connects the bottom surface 224 of the first tier IC die 120-1 to the top surface 220 of the second tier IC die 120-2. Additional tiers of IC dies may be stacked on the second tier IC die 120-2, if desired.

The interconnects 502 also connects the vias 140 of the first via guard structure 110-1 of the first tier IC die 120-1 to the via stack 250-2 of the second tier IC die 120-2. In this manner, the second via guard structure 110-2 of the second tier IC die 120-2 is effectively coupled to ground 408 through to the via stack 250-1 and first via guard structure 110-1 of the first tier IC die 120-1.

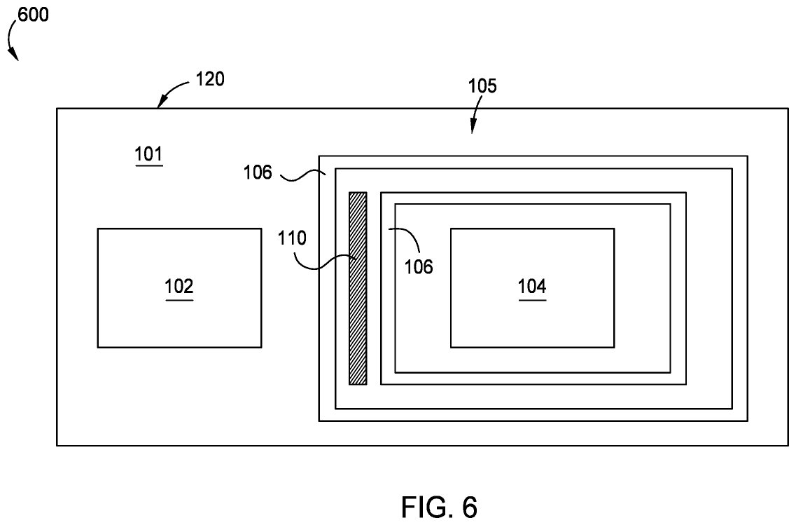

FIG. 6 is a plan view of an electronic device 600 having a substrate noise isolation structure 105 that includes via guard structure 110 disposed between a noise source circuit 102 and a noise receiver circuit 104, according to another example. In the present example, the substrate noise isolation structure 105 comprises a plurality of guard rings 106 separated by the via guard structure 110. The guard rings 106 surround the noise receiver circuit 104. Although only two guard ring 106 are shown in FIG. 6, additional guard rings 106 may be utilized. Additionally, the via guard structure 110 can be disposed inward of the inner guard ring 106 or outward of the outer guard ring 106. Optionally, additional via guard structures 110 may be utilized.

The inner guard ring 106 surrounds the noise receiver circuit 104. The outer guard ring 106 also surrounds the noise receiver circuit 104, and also surrounds the guard ring 106. The via guard structure 110 is disposed at least between the portions of the inner and outer guard rings 106 that are between the noise source circuit 102 and the noise receiving circuit 104.

In FIG. 6, the via guard structure 110 is shown aligned in the Y-axis direction, with the via guard structure 110 separating the noise source circuit 102 and the noise receiving circuit 104 in the X-axis direction. However, both the via guard structure 110 and one of the noise source or receiving circuit 102, 104 may be rotated 90 degrees such that the via guard structure 110 is aligned in the X-axis direction, with the via guard structure 110 separating the noise source circuit 102 and the noise receiving circuit 104 in the Y-axis direction.

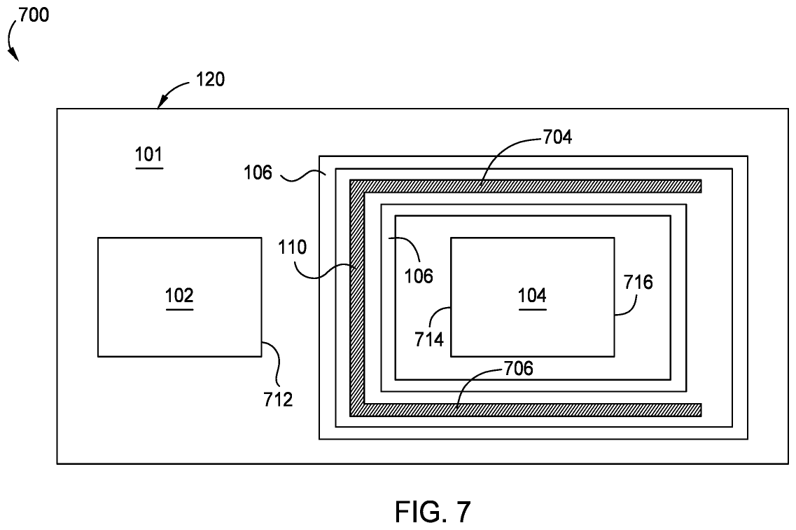

FIG. 7 is a plan view of another electronic device 700 having a substrate noise isolation structure 105 that includes via guard structure 110 disposed on three sides of a noise receiver circuit 104 according to another example. At least a portion of the via guard structure 110 is disposed between a noise source circuit 102 and a noise receiver circuit 104. In the example depicted in FIG. 7, the substrate noise isolation structure 105 comprises a plurality of guard rings 106 separated by the via guard structure 110. The guard rings 106 surround the noise receiver circuit 104. Although only two guard ring 106 are shown, additional guard rings 106 may be utilized. Additionally, the via guard structure 110 can be disposed inward of the inner guard ring 106 or outward of the outer guard ring 106. Optionally, additional via guard structures 110 may be utilized.

The inner guard ring 106 surrounds the noise receiver circuit 104. The outer guard ring 106 also surrounds the noise receiver circuit 104 and also surrounds the guard ring 106. The via guard structure 110 is disposed at least between the portions of the inner and outer guard rings 106 that are between facing sides 712, 714 of the noise source circuit 102 and the noise receiving circuit 104.

In FIG. 7, the via guard structure 110 is shown having three walls 702, 704, 706. Although not shown in FIG. 7, each of the walls 702, 704, 706 include a plurality of vias 140. The first wall 702 of the via guard structure 110 is between the facing sides 712, 714 of the noise source circuit 102 and the noise receiving circuit 104. The second wall 704 and the third wall 706 are connected (e.g., in the same un-doped region 114) to the first wall 702. The second wall 704 and the third wall 706 are disposed on opposite sides of the noise receiving circuit 104. A side 716 of the noise receiving circuit 104 facing away from the noise source circuit 102 is not bounded by the via guard structure 110.

In FIG. 7, the first wall 702 of via guard structure 110 is shown aligned in the Y-axis direction, with the first wall 702 of the via guard structure 110 separating the noise source circuit 102 and the noise receiving circuit 104 in the X-axis direction. However, both the via guard structure 110 and one of the noise source or receiving circuit 102, 104 may be rotated 90 degrees such that the first wall 702 of the via guard structure 110 is aligned in the X-axis direction, with the first wall 702 of the via guard structure 110 separating the noise source circuit 102 and the noise receiving circuit 104 in the Y-axis direction.

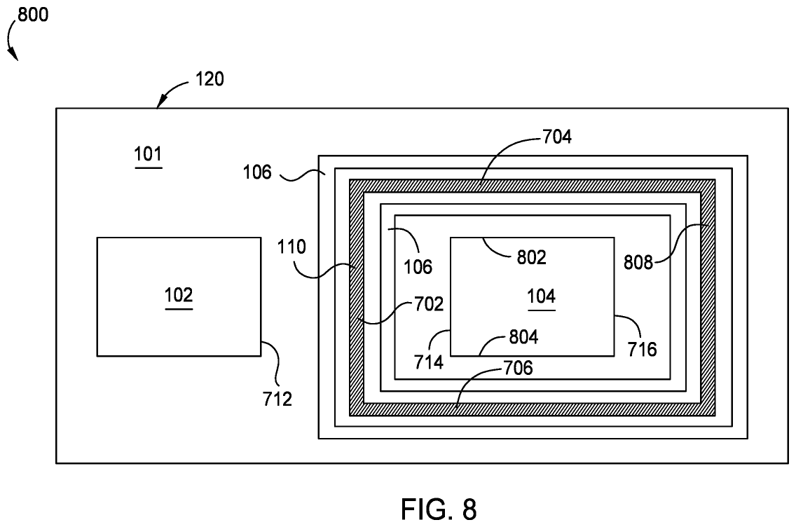

FIG. 8 is a plan view of another electronic device 800 having a substrate noise isolation structure 105 that includes via guard structure 110 disposed on all sides of a noise receiver circuit 104 according to another example. As with all the examples described herein, least a portion of the via guard structure 110 is disposed between the noise source circuit 102 and the noise receiver circuit 104. In the example depicted in FIG. 8, the substrate noise isolation structure 105 comprises a plurality of guard rings 106 separated by the via guard structure 110. The guard rings 106 surround the noise receiver circuit 104. Although only two guard ring 106 are shown, additional guard rings 106 may be utilized. Additionally, the via guard structure 110 can be disposed inward of the inner guard ring 106 or outward of the outer guard ring 106. Optionally, additional via guard structures 110 may be utilized.

The inner guard ring 106 surrounds the noise receiver circuit 104. The via guard structure 110 surrounds the inner guard ring 106 and the noise receiver circuit 104. The outer guard ring 106 surrounds the via guard structure 110, the inner guard ring 106, and the noise receiver circuit 104.

In FIG. 8, the via guard structure 110 is shown having four walls 702, 704, 706, 808. Although not shown in FIG. 8, each of the walls 702, 704, 706, 808 include a plurality of vias 140. The first wall 702 of the via guard structure 110 is between the facing sides 712, 714 of the noise source circuit 102 and the noise receiving circuit 104. The second wall 704, the third wall 706, and the fourth wall 808 are connected (e.g., in the same un-doped region 114) to the first wall 702. The second wall 704 and the third wall 706 are disposed on opposite sides of the noise receiving circuit 104. The fourth wall 808 of the via guard structure 110 faces the side 716 of the noise receiving circuit 104 that faces away from the noise source circuit 102.

In FIG. 8, the first wall 702 of via guard structure 110 is shown aligned in the Y-axis direction, with the first wall 702 of the via guard structure 110 separating the noise source circuit 102 and the noise receiving circuit 104 in the X-axis direction. However, both the via guard structure 110 and one of the noise source or receiving circuit 102, 104 may be rotated 90 degrees such that the first wall 702 of the via guard structure 110 is aligned in the X-axis direction, with the first wall 702 of the via guard structure 110 separating the noise source circuit 102 and the noise receiving circuit 104 in the Y-axis direction.

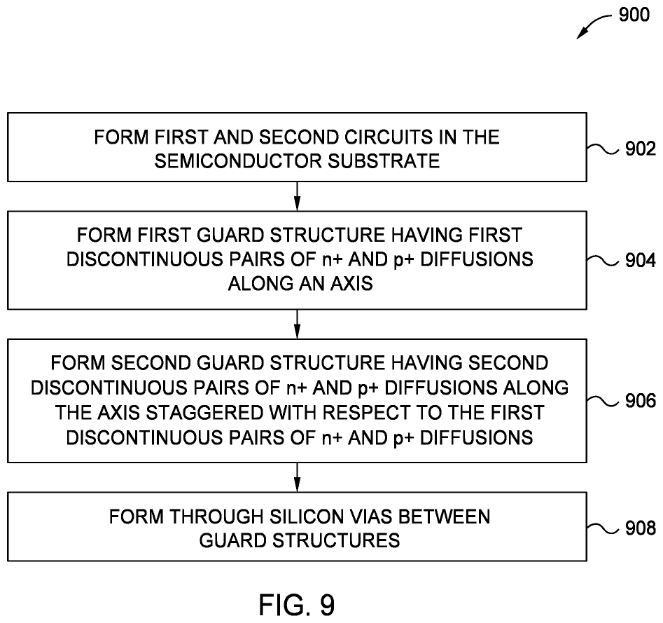

FIG. 9 is a flow diagram depicting a method 900 of manufacturing an electronic device according to an example. The method 900 begins at operation 902, where first and second circuits are formed in the semiconductor substrate. In an example, the first circuit, the second circuit, or both include FinFETs. The first circuit is a noise source circuit 102 and the second circuit is noise receiving circuit 104.

At operation 904, a first guard structure 106 is formed in the semiconductor substrate 101 between the first circuit and the second circuit. The first guard structure 106 includes first discontinuous pairs of N+ and P+ diffusions disposed along a first axis. The first guard structure 106 may bound 1, 2, 3 or all sides of at least one of the circuits, 102, 104.

At operation 906, a second guard structure 106 is formed in the semiconductor substrate 101 between the first and second circuit. The second guard structure 106 includes second discontinuous pairs of N+ and P+ diffusions disposed along the first axis and staggered with respect to the first pairs of N+ and P+ diffusions. In an example, the first and second guard structures 106 are walls disposed between the first and second circuits. In another example, the first and second guard structures are sides of guard rings surrounding one of the first or second circuits. The second guard structure 106 may bound 1, 2, 3 or all sides of at least one of the circuits, 102, 104. The second guard structure 106 may be circumscribed by the first guard structure 106.

At operation 908, a plurality of vias 140 are formed in the semiconductor substrate 101. The vias 140 form via guard structure 110 may be disposed to either side of the guard structures 106. The vias 140, which are configured to be coupled to ground when in use, may be formed in an un-doped region of the substrate 101. The via guard structure 110 may be disposed between portions of guard structures 106 that are disposed between the first and second circuits. The via guard structure 110 may bound 1, 2, 3 or all sides of at least one of the circuits, 102, 104.

Techniques for utilizing substrate noise isolation structures in electronic devices have been described. In general, a substrate noise isolation structure includes guard structures and a via guard structure disposed between two circuits. The guard structures have discontinuous pairs of N+ and P+ diffusions. In some examples, the via guard structure is disposed between the circuits. In some examples, the discontinuous pairs of N+ and P+ diffusions are staggered so that the gaps therebetween are not aligned. The described techniques provide for improved substrate noise isolation, particularly in technologies where continuous diffusion regions cannot be formed along at least one dimension of the substrate.

The N+/P+ guard ring pairs and grounded TSVs of the substrate noise isolation structure effectively suppresses substrate noise and strengthens the isolation performance in 3D technology, particularly with thinned silicon substrates. By reducing substrate noise, the risk of performance degradation, timing errors, and functional failures due to noise-induced glitches or disturbances is significantly reduced, thereby improving the overall reliability and lifespan of electronic devices that incorporate the grounded TSVs. Moreover, by effectively reducing substrate noise in thinned-down substrates, noise sensitive analog circuits in a 3D stacked devices may be successful integrated. The novel noise isolation structure is compatible with existing fabrication processes used in CMOS and 3D stacking technologies, making the novel noise isolation structure easily and cost-effectively incorporated in a wide variety of electronic devices.

While the foregoing is directed to specific examples, other and further examples may be devised without departing from the basic scope thereof, and the scope thereof is determined by the claims that follow.

What is claimed is:

1. An electronic device, comprising:
a first circuit and a second circuit formed on a substrate;
a first guard structure formed in the substrate and disposed between the first circuit and the second circuit; and
a plurality of vias formed through the substrate adjacent the first guard structure, the plurality of vias disposed between the first circuit and the second circuit.

2. The electronic device of claim 1, wherein the first guard structure comprises:
a first group of discontinuous pairs of N+ and P+ wells disposed along a first column.

3. The electronic device of claim 2, wherein the first guard structure comprises:
a second group of discontinuous pairs of N+ and P+ wells disposed along a second column that runs adjacent the first column.

4. The electronic device of claim 3, wherein the pairs of N+ and P+ wells comprising the first column are staggered relative to the pairs of N+ and P+ wells comprising the second column.

5. The electronic device of claim 4, wherein at least one of the pairs of N+ and P+ wells comprising the first column is overlapped with at least one of the pairs of N+ and P+ wells comprising the second column in a direction perpendicular to a direction of the first column.

6. The electronic device of claim 4, wherein a first pair of the pairs of N+ and P+ wells comprising the first column is overlapped with two of the pairs of N+ and P+ wells comprising the second column in a direction perpendicular to a direction of the first column.

7. The electronic device of claim 1, wherein the plurality of vias formed through the substrate comprises:
a first column of vias formed in an un-doped region of the substrate.

8. The electronic device of claim 1, wherein the plurality of vias formed through the substrate comprises:
a plurality of via columns formed through the substrate between the first and second circuits.

9. The electronic device of claim 1 further comprising:
a second guard structure circumscribing both the plurality of vias and the first guard structure.

10. The electronic device of claim 1 further comprising:
a front end of the line (FEOL) region formed on the substrate and containing a least a portion of the first circuit and the second circuit;
a back end of the line (BEOL) region formed on the FEOL region; and
a via stack formed through the FEOL and BEOL regions, the via stack electrically connected to one of the plurality of vias formed through the substrate.

11. An electronic device, comprising:
a first substrate;
a front end of the line (FEOL) region formed on the first substrate and containing a least a portion of a first circuit and a second circuit;
a back end of the line (BEOL) region formed on the FEOL region, the first substrate, the FEOL region and the BEOL region comprising at least a portion of a first integrated circuit (IC) die;
a first guard structure formed in the first substrate and disposed between the first circuit and the second circuit, the first guard structure comprising a first group of discontinuous pairs of N+ and P+ wells disposed along a first column;
a second guard structure formed in the first substrate and disposed between the first circuit and the second circuit, the second guard structure comprising a second group of discontinuous pairs of N+ and P+ wells disposed along a first column;
a plurality of vias formed through the first substrate, the plurality of vias disposed between the first guard structure and the second guard structure, the first guard structure, the second guard structure, and the plurality of vias forming a first noise isolation structure; and
a via stack formed through the FEOL and BEOL regions, the via stack electrically connected to one of the plurality of vias formed through the first substrate.

12. The electronic device of claim 11, wherein the first guard structure comprises:
a second group of discontinuous pairs of N+ and P+ wells disposed along a second column that runs adjacent the first column.

13. The electronic device of claim 12, wherein the pairs of N+ and P+ wells comprising the first column are staggered relative to the pairs of N+ and P+ wells comprising the second column.

14. The electronic device of claim 13, wherein at least one of the pairs of N+ and P+ wells comprising the first column is overlapped with at least one of the pairs of N+ and P+ wells comprising the second column in a direction perpendicular to a direction of the first column.

15. The electronic device of claim 13, wherein a first pair of the pairs of N+ and P+ wells comprising the first column is overlapped with two of the pairs of N+ and P+ wells comprising the second column in a direction perpendicular to a direction of the first column.

16. The electronic device of claim 11, wherein the plurality of vias formed through the first substrate comprises:
a first column of ground vias circumscribed by the first guard structure.

17. The electronic device of claim 16, wherein the plurality of vias formed through the first substrate comprises:
a first column of ground vias and a second column of ground vias, the first and second columns of ground vias disposed between the first guard structure and the second guard structure, the first and second columns of ground vias disposed between the first circuit and the second circuit.

18. The electronic device of claim 17, wherein the vias comprising the second column of vias are offset relative to the vias comprising the first column of vias.

19. The electronic device of claim 11 further comprising:
a second IC die stacked on the first IC die, the second IC die comprising:
a second noise isolation structure disposed between first and second circuits of the second IC die, the second noise isolation structure comprising:
first and second guard structures separated by a plurality of grounded vias, the first and second guard structures separated by a plurality of grounded vias, the plurality of grounded vias of the second IC die electrically connected to the plurality of grounded vias and via stack of the first IC die.

20. A method of manufacturing an electronic device, comprising:
forming a first circuit and a second circuit on a substrate;
forming a first guard structure in the substrate between the first circuit and the second circuit, the first guard structure including first discontinuous pairs of N+ and P+ diffusions arranged along an axis;
forming a second guard structure in the substrate between the first circuit and the second circuit, the first guard structure including second discontinuous pairs of N+ and P+ diffusions arranged along the axis, the first discontinuous pairs staggered relative to the second discontinuous pairs; and
forming a plurality of vias through the substrate between the first guard structure and the second guard structure, the plurality of vias formed between the first circuit and the second circuit.
